(19) United States
(12) Patent Application Publication
(10) Pub. No.: US 2012/0118231 A1
(43) Pub. Date: May 17, 2012

(54) SUBSTRATE PROCESSING METHOD, STORAGE MEDIUM, AND SUBSTRATE PROCESSING APPARATUS

(75) Inventors: Toshio TAKAGI, Nirasaki-Shi (JP); Hiroshi KANEKO, Nirasaki-Shi (JP); Teruo IWATA, Nirasaki-Shi (JP); Tamaki TAKEYAMA, Nirasaki-Shi (JP); Akinobu KAKIMOTO, Nirasaki-Shi (JP)

(73) Assignee: TOKYO ELECTRON LIMITED, Minato-Ku (JP)

(21) Appl. No.: 13/355,151

(22) Filed: Jan. 20, 2012

Related U.S. Application Data
(63) Continuation of application No. 11/817,717, filed on Sep. 4, 2007.

(30) Foreign Application Priority Data
Mar. 10, 2005 (JP) 2005-067777

(51) Int. Cl. C23C 16/455; C23C 16/06; C23C 16/458; C23C 16/52

(52) U.S. Cl. 118/696; 118/726; 118/728; 118/729; 118/733

(57) ABSTRACT

A method of processing a substrate by a substrate processing apparatus is disclosed. The substrate processing apparatus includes a processing container including a first space where a first processing gas or a second processing gas is supplied onto the substrate and a second space formed around the first space; a first exhaust unit configured to evacuate the first space; and a second exhaust unit configured to evacuate the second space. The method includes a first step of supplying the first processing gas into the first space; a second step of discharging the first processing gas from the first space; a third step of supplying the second processing gas into the first space; and a fourth step of discharging the second processing gas from the first space; wherein the pressure in the second space is adjusted by a pressure-adjusting gas supplied into the second space.

### CROSS-REFERENCE TO RELATED APPLICATIONS

The present application is a continuation of U.S. application Ser. No. 11/817,717, filed on Sep. 4, 2007, which is a National Stage of PCT/JP2006/302928 filed Feb. 20, 2006, and claims the benefit of priority under 35 U.S.C. 119 from Japanese Application No. 2005-067777 filed Mar. 10, 2005; the entire contents of which are hereby incorporated herein by reference.

### TECHNICAL FIELD

The present invention generally relates to production of semiconductor devices. More particularly, this invention relates to a vapor-phase deposition method for forming a dielectric film or a metal film.

### BACKGROUND ART

In conventional semiconductor device manufacturing technology, the MOCVD method is normally used to form a high-quality metal film, insulating film, or semiconductor film on a substrate.

Meanwhile, in these days, research efforts on the atomic layer deposition (ALD) method are being made especially as a method of forming gate insulating films of ultra-fine semiconductor devices. In the ALD method, high-dielectric-constant films (so called high-K dielectric films) are deposited atomic layer by atomic layer on a substrate.

More specifically, in the ALD method, metal compound molecules containing a metallic element that constitutes a high-K dielectric film are supplied in the form of vapor-phase material gas (material gas) into a processing space where a substrate is placed so that about one molecular layer of the metal compound molecules are chemisorbed on the surface of the substrate. Next, the vapor-phase material gas is purged from the processing space and an oxidizer (oxidizing gas) is supplied into the processing space to decompose the metal compound molecules chemisorbed on the surface of the substrate and thereby to form about one molecular layer of metal oxide film.

Then, the oxidizer is purged from the processing space and the above steps are repeated to form a metal oxide film or a high-K dielectric film with a desired thickness.

Thus, the ALD method makes use of chemisorption of compound molecules on the surface of a substrate and therefore has an advantage especially in terms of step coverage. The ALD method also makes it possible to form a high-quality film at a temperature between 200 and 300° C. or lower. Therefore, the ALD method is not only suitable to form gate insulating films of ultrafast transistors but also suitable for the production of a memory cell capacitor of a DRAM where it is required to form a dielectric film on a foundation layer having a complex shape.

FIG. 1 is a schematic cross-sectional view of a substrate processing apparatus 100 provided as an example of a conventional substrate processing apparatus that can form a film by the ALD method.

As shown in FIG. 1, the substrate processing apparatus 100 comprises a processing container 111 including an external container 111B made of an aluminum alloy and a cover plate 111A disposed so as to cover an opening of the external container 111B and a reaction container 112 made of, for example, quartz and disposed in a space formed by the external container 111B and the cover plate 111A. A processing space A10 is formed in the reaction container 112. The reaction container 112 includes an upper container 112A and a lower container 112B.

The bottom of the processing space A10 is formed by a holding table 113 for holding a substrate W10. The holding table 113 has a guard ring 114 made of quartz glass and disposed so as to surround the substrate W10. The holding table 113 extends downward from the external container 111B and is configured to move up and down in the external container 111B between an upper-end position and a lower-end position. Although not shown, a substrate input/output opening is provided in the external container 111B. When placed at the upper-end position, the holding table 113 forms the processing space A10 together with the reaction container 112. When the holding table 113 is placed at the lower-end position, it becomes possible to carry the substrate W10 into the processing container 111 or out of the processing container 111 through a gate valve (not shown) provided in the processing container 111.

The holding table 113 is held by a rotational shaft 120, which is held in a bearing 121 by a magnetic seal 122, so as to be able to rotate and move up and down. The space where the rotational shaft 120 moves up and down is hermetically closed by a confining wall such as a bellows 119.

At corresponding ends of the processing space A10 of the substrate processing apparatus 100, exhaust openings 115A and 115B for evacuating the processing space A10 are provided so as to face each other across the substrate W10. The exhaust openings 115A and 115B, respectively, lead to high-speed rotary valves 117A and 117B that are connected, respectively, to exhaust pipes 156A and 156B. Also at corresponding ends of the processing space A10, bird's beak-shaped processing gas nozzles 116A and 116B are provided to regulate the flow of gas into the high-speed rotary valves 117A and 117B. The processing gas nozzles 116A and 116B are disposed so as to face, respectively, the high-speed rotary valves 117A and 117B and to face each other across the substrate W10.

The processing gas nozzle 116A is connected via a switching valve 152A to a gas line 154A, a purge line 155A, and a gas exhaust line 153A. Similarly, the processing gas nozzle 116B is connected via a switching valve 152B to a gas line 154B, a purge line 155B, and a gas exhaust line 153B.

For example, a first processing gas supplied from the gas line 154A and a purge gas supplied from the purge line 155A are introduced via the switching valve 152A and the processing gas nozzle 116A into the processing space A10. It is also possible to discharge the first processing gas supplied from the gas line 154A and the purge gas supplied from the purge line 155A via the switching valve 152A and the gas exhaust line 153A.

Similarly, a second processing gas supplied from the gas line 154B and a purge gas supplied from the purge line 155B are introduced via the switching valve 152B and the processing gas nozzle 116B into the processing space A10. It is also possible to discharge the second processing gas supplied from the gas line 154B and the purge gas supplied from the purge line 155B via the switching valve 152B and the gas exhaust line 153B.

The first processing gas (material gas) introduced via the processing gas nozzle 116A flows along the surface of the substrate W10 in the processing space A10 formed in the reaction container 112 and is discharged via the exhaust opening 115B and the high-speed rotary valve 117B at the opposite end. Similarly, the second processing gas (oxidizing gas) introduced via the processing gas nozzle 116B flows along the surface of the substrate W10 in the processing space A10 formed in the reaction container 112 and is discharged via the exhaust opening 115A and the high-speed rotary valve 117A at the opposite end.

Thus, the substrate processing apparatus 100 is configured to deposit a film atomic layer by atomic layer by alternately sending the first processing gas from the processing gas nozzle 116A to the exhaust opening 115B and sending the second processing gas from the processing gas nozzle 116B to the exhaust opening 115A.

In the ALD method described above, the uniformity of a film formed on a substrate is practically determined by the saturating amount of material molecules to be adsorbed on a substrate. Therefore, compared with a conventional CVD method, the ALD method has an advantage in terms of within-wafer uniformity in, for example, thickness and quality of a film formed on a substrate.
[Patent document 1] Japanese Patent Application Publication No. 2004-6733

### DISCLOSURE OF INVENTION

### Problems to be Solved by the Invention

One technical problem with the ALD method is that it is difficult to efficiently supply and purge a material gas and an oxidizing gas into and from a processing container. For example, in the ALD method, it is difficult to repeat a cycle of supplying and purging a material gas and supplying and purging an oxidizing gas efficiently at short intervals. In other words, reducing the time necessary to perform this cycle is one of the hurdles in improving the productivity of the ALD method.

Especially, it is difficult to completely purge a material gas remaining in or adhering to a processing container. For example, even if the amount of a purge gas is increased, the efficiency in purging a material gas is not improved dramatically.

One widely-used way to solve this problem is to employ a dual space structure for a processing container as in the case of the substrate processing apparatus 100. A dual space structure makes it possible to minimize the space where a material gas flows and thereby to minimize the amount of the material gas remaining in or adhering to the processing container.

The semiconductor processing apparatus 100 has a dual space structure where the processing space A10 is formed in the internal space of the processing container 111 by the reaction container 112 made of quartz.

This structure makes it possible to greatly reduce the volume of a space (processing space) where a material gas flows relative to the volume of the entire space in a processing container and thereby makes it possible to reduce the time necessary to supply and purge a material gas into and from the processing space. Especially, this structure has an advantage in reducing the time necessary to purge a material gas from the processing space.

If the entire space in a processing container is reduced greatly instead of employing a dual space structure, it becomes difficult to carry a substrate into or out of the processing container. Also, with such a structure, it becomes difficult to lay out mechanisms for supplying and purging a material gas and an oxidizing gas into and from the processing container.

To obviate the above problems, the substrate processing apparatus 100 employs a dual space structure where the processing space A10 is formed in the internal space of the processing container 111 by the reaction container 112, and also employs a structure where the holding table forming the bottom of the processing space A10 moves downward to the lower-end position when a substrate is carried into or out of the processing space A10.

One problem with the substrate processing apparatus 100 configured as described above is that a gap is formed between the edge of the holding table 113 and the opening of the reaction container 112. As a result, the processing space A10 and a space (external space A20) outside of the processing space A10 are connected via the gap.

When forming a film by the ALD method using the substrate processing apparatus 100, if the difference in pressure between the processing space A10 and the external space A20 increases, the gap may cause a material gas (processing gas) supplied to the processing space A10 to behave in such a manner that the quality, such as the uniformity, of the film is degraded.

In the ALD method, a film is formed by repeating the steps of 1) supplying a first processing gas (material gas) into the processing space A10, 2) purging the first processing gas, 3) supplying a second processing gas (oxidizing gas) into the processing space A10, and 4) purging the second processing gas. In this process, if the pressure in the processing space A10 increases, the difference in pressure between the processing space A10 and the external space A20 also increases.

Increase in the pressure difference may cause a processing gas to flow from the processing space A10 into the external space A20 or from the external space A20 back into the processing space A10 and thereby negatively affect a film forming process.

More specifically, such a gas flow may affect deposition rate distribution and degrade the uniformity in thickness or quality of a film to be formed.

FIG. 2 is an enlarged cross-sectional view of a portion of the substrate processing apparatus 100 taken along line X-X shown in FIG. 1. In FIG. 2, the same reference numbers are used for parts corresponding to those shown in FIG. 1, and descriptions of those parts are omitted.

As shown in FIG. 2, the processing space A10 and the external space A20 are connected, for example, via a gap around the holding table 113. More specifically, the processing space A10 and the external space A20 are connected via a gap formed between the guard ring 114 surrounding a substrate held on the holding table 113 and an opening of the lower container 112B.

For example, a processing gas supplied into the processing space A10 may be discharged into the external space A20 through the gap and the discharged processing gas may flow back into the processing space A10. This may adversely affect formation of a film on a substrate.

Especially, such irregular flow of the processing gas may adversely affect the uniformity in thickness or quality of a film to be formed on a substrate. Also, the processing gas flowing into the external space A20 may adhere to its wall surface.

One object of the present invention is to provide a new and useful substrate processing method that solves the above problems, a storage medium containing a program for performing the substrate processing method, and a substrate processing apparatus that performs the substrate processing method.

A more specific object of the present invention is, in an apparatus or method for forming a film by alternately supplying multiple processing gases, to control the flow of the processing gases in a space where a substrate is processed and thereby to improve the uniformity in thickness of a film to be formed on the substrate.

### Means for Solving the Problems

A first aspect of the present invention provides a method of processing a substrate by a substrate processing apparatus that comprises a processing container including a first space where the substrate is placed and where a first processing gas or a second processing gas is supplied onto the substrate and a second space formed around the first space and connected to the first space; a first exhaust unit configured to evacuate the first space; and a second exhaust unit configured to evacuate the second space. The method comprises a first step of supplying the first processing gas into the first space; a second step of discharging the first processing gas from the first space; a third step of supplying the second processing gas into the first space; and a fourth step of discharging the second processing gas from the first space; wherein the pressure in the second space is adjusted by a pressure-adjusting gas supplied into the second space.

A second aspect of the present invention provides a storage medium having program code stored therein for causing a substrate processing apparatus to perform a method of processing a substrate. The substrate processing apparatus comprises a processing container including a first space where the substrate is placed and where a first processing gas or a second processing gas is supplied onto the substrate and a second space formed around the first space and connected to the first space; a first exhaust unit configured to evacuate the first space; and a second exhaust unit configured to evacuate the second space. The method comprises a first step of supplying the first processing gas into the first space; a second step of discharging the first processing gas from the first space; a third step of supplying the second processing gas into the first space; and a fourth step of discharging the second processing gas from the first space; wherein the pressure in the second space is adjusted by a pressure-adjusting gas supplied into the second space.

A third aspect of the present invention provides an apparatus for processing a substrate. The apparatus comprises a processing container including a first space where the substrate is placed and a second space formed around the first space and connected to the first space; a pair of processing gas supply units disposed so as to face each other across the substrate and configured to supply processing gases into the first space; a pair of processing gas exhaust units disposed so as to face each other across the substrate and configured to discharge the processing gases; a pressure-adjusting gas supply unit configured to supply a pressure-adjusting gas for adjusting the pressure in the second space into the second space; and a pressure-adjusting gas exhaust unit configured to evacuate the second space.

### Advantageous Effect of the Invention

The present invention relates to an apparatus or method for forming a film by alternately supplying multiple processing gases and makes it possible to control the flow of the processing gases in a space where a substrate is processed and thereby to improve the uniformity in thickness of a film to be formed on the substrate.

### BRIEF DESCRIPTION OF THE DRAWINGS

FIG. 1 is a drawing illustrating a conventional substrate processing apparatus;

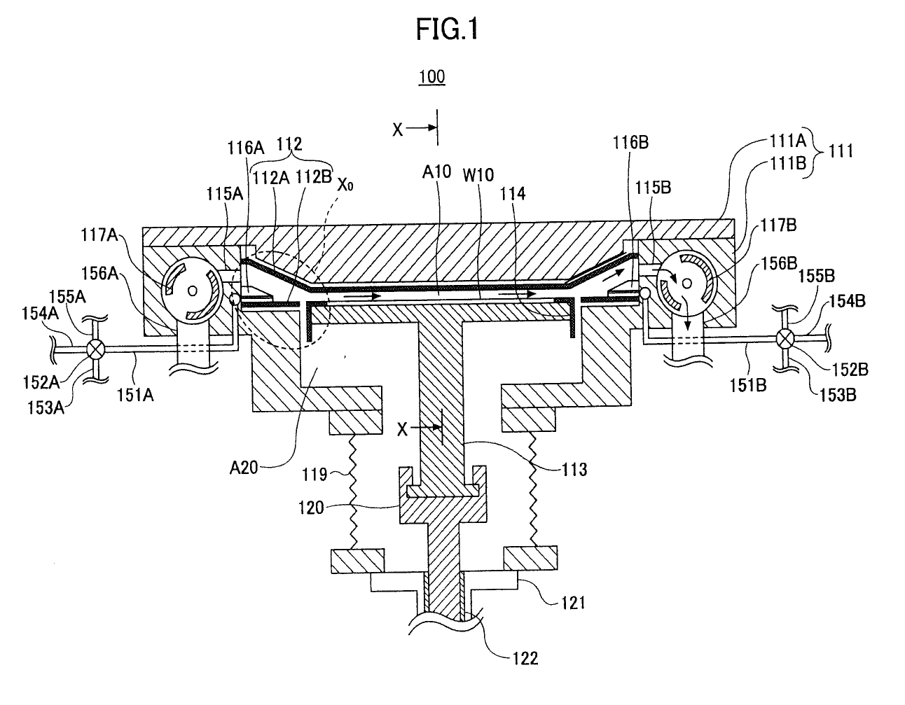

FIG. 2 is an enlarged view of a portion of the substrate processing apparatus shown in FIG. 1;

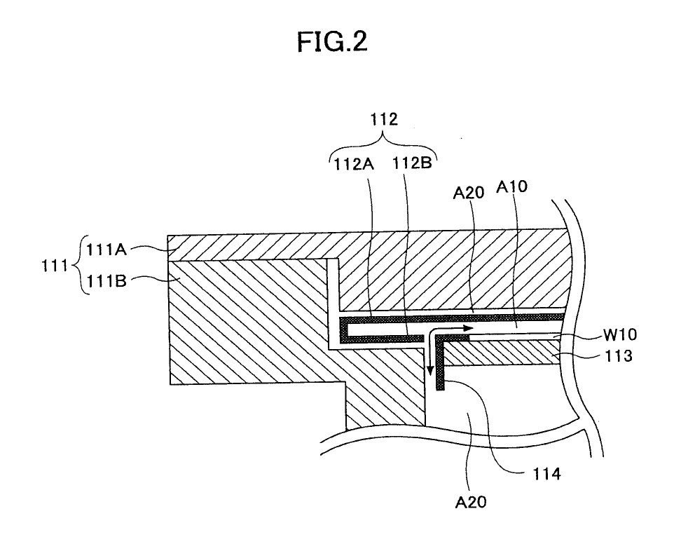

FIG. 3 is a schematic diagram (1) of a substrate processing apparatus according to a first embodiment;

FIG. 4 is a schematic diagram (2) of the substrate processing apparatus according to the first embodiment;

FIG. 5 is an enlarged view of a portion of the substrate processing apparatus shown in FIG. 3;

FIG. 6 is a drawing illustrating a schematic configuration of the substrate processing apparatus according to the first embodiment;

FIG. 7 is a flowchart showing a substrate processing method according to the first embodiment;

FIG. 8 is a graph used to show improvements by a film forming method using a pressure-adjusting gas;

FIG. 9 is an enlarged view of a portion of a substrate processing apparatus according to a second embodiment; and

FIG. 10 is a graph showing the results of forming films by the substrate processing apparatus shown in FIG. 9.

### EXPLANATION OF REFERENCES

10, 100 Substrate processing apparatus
11, 111 Processing container
11A, 111A Cover plate
11B, 111B External container
12, 112 Reaction container
12A, 112A Upper container
12B, 112B Lower container
13, 113 Holding table
14, 114 Guard ring
15A, 15B, 115A, 115B Exhaust opening
16A, 16B, 116A, 116B Processing gas nozzle
17A, 17B, 117A, 117B High-speed rotary valve
19, 119 Bellows
20, 120 Rotational shaft
21, 121 Bearing
22, 122 Magnetic seal
52A, 52B, 152A, 152B Switching valve
54A, 54B Gas line
56 Purge gas introducing line
57 Exhaust line

### BEST MODE FOR CARRYING OUT THE INVENTION

### First Embodiment

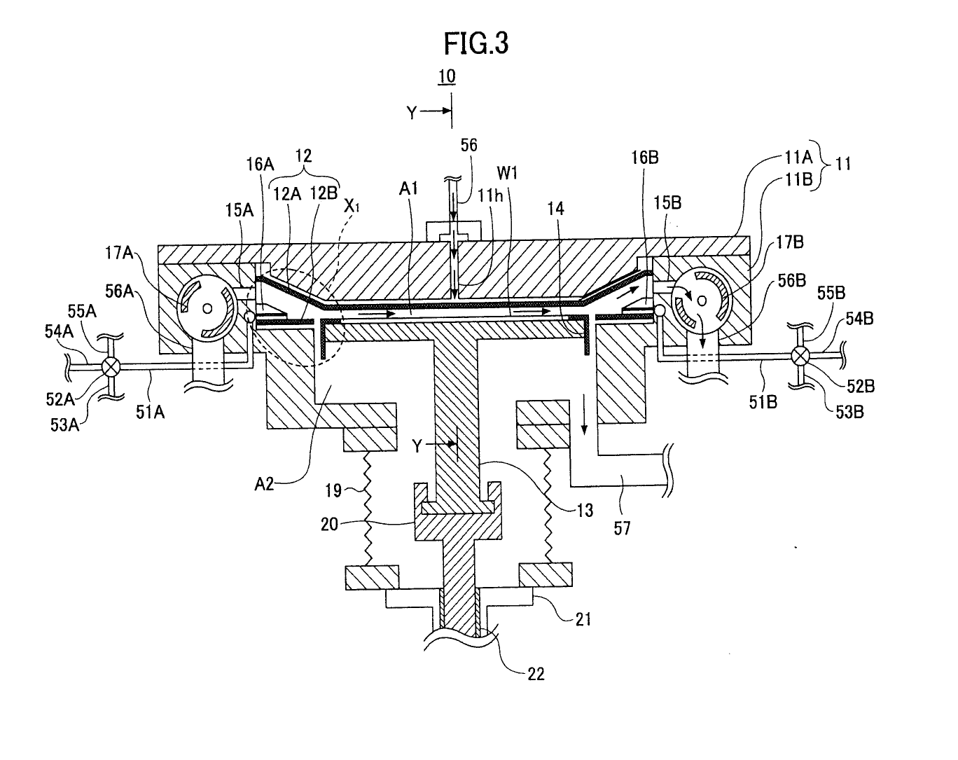

FIG. 3 is a schematic cross-sectional view of a substrate processing apparatus 10 according to a first embodiment of the present invention provided as an example of a substrate processing apparatus that can form a film by the ALD method.

As shown in FIG. 3, the substrate processing apparatus 10 comprises a processing container 11 including an external container 11B made of an aluminum alloy and a cover plate 11A disposed so as to cover an opening of the external container 11B, and a reaction container 12 made of, for example, quartz and disposed in a space formed by the external container 11B and the cover plate 11A. A processing space A1 is formed in the reaction container 12. The reaction container 12 includes an upper container 12A and a lower container 12B.

Thus, the interior space of the processing container 11 is substantially divided into the processing space A1 formed in the reaction container 12 and an external space A2 that surrounds the processing space A1 and includes a gap between, for example, the reaction container 12 and the inner wall of the processing container 11.

The bottom of the processing space A1 is formed by a holding table 13 for holding a substrate W1. The holding table 13 has a guard ring 14 made of quartz glass and disposed so as to surround the substrate W1. The holding table 13 extends downward from the external container 11B and is configured to move up and down in the external container 11B between an upper-end position and a lower-end position. Although not shown, a substrate input/output opening is provided in the external container 11B. When placed at the upper-end position, the holding table 13 forms the processing space A1 together with the reaction container 12. More specifically, at the upper-end position, the holding table 13 covers a substantially circular opening formed in the lower container 12B of the reaction container 12. When the holding table 13 is at the upper-end position, the bottom of the lower container 12B and the substrate W1 form a substantially flat surface.

The holding table 13 is held by a rotational shaft 20, which is held in a bearing 21 by a magnetic seal 22, so as to be able to rotate and move up and down. The space where the rotational shaft 20 moves up and down is hermetically closed by a confining wall such as a bellows 19.

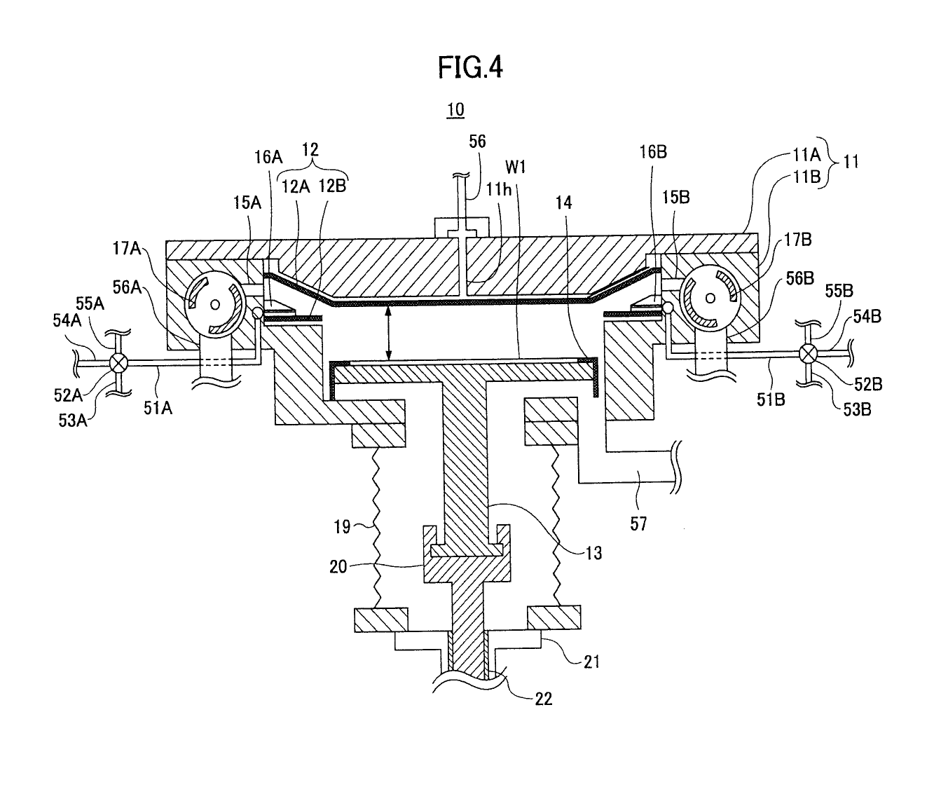

In FIG. 3, the holding table 13 is placed at the upper-end position and the processing space A1 is formed so that a film can be deposited on the substrate W1 on the holding table 13. In FIG. 4, the holding table 13 is placed at the lower-end position and the substrate W1 is positioned at the same height as that of a substrate input/output opening (not shown) formed in the external container 11B. When the holding table 13 is at the lower-end position as shown in FIG. 4, the substrate W1 can be carried into or out of the processing space A1 by, for example, driving a mechanism such as a lifter pin (not shown) for holding the substrate W1.

The central portion of the cover plate 11A is thicker than other portions. Since the processing space A1 is formed by the holding table 13 placed at the upper-end position and the reaction container 12 disposed in a space formed by the external container 11B and the cover plate 11A, the height or the volume of the processing space A1 is small in the central portion where the substrate W1 is placed and becomes larger as it nears the ends.

In the substrate processing apparatus 10, exhaust openings 15A and 15B for evacuating the processing space A1 are provided at corresponding ends of the processing space A1 so as to face each other across the substrate W1. The exhaust openings 15A and 15B, respectively, lead to high-speed rotary valves 17A and 17B that are connected, respectively, to exhaust pipes 56A and 56B.

Also at corresponding ends of the processing space A1, bird's beak-shaped processing gas nozzles 16A and 16B are provided to regulate the flow of gas into the high-speed rotary valves 17A and 17B. The processing gas nozzles 16A and 16B are disposed so as to face, respectively, the high-speed rotary valves 17A and 17B and to face each other across the substrate W1.

The processing gas nozzle 16A is connected via a switching valve 52A to a gas line 54A, a purge line 55A, and a gas exhaust line 53A. Similarly, the processing gas nozzle 16B is connected via a switching valve 52B to a gas line 54B, a purge line 55B, and a gas exhaust line 53B.

For example, a first processing gas supplied from the gas line 54A and a purge gas supplied from the purge line 55A are introduced via the switching valve 52A and the processing gas nozzle 16A into the processing space A1. It is also possible to discharge the first processing gas supplied from the gas line 54A and the purge gas supplied from the purge line 55A via the switching valve 52A and the gas exhaust line 53A.

Similarly, a second processing gas supplied from the gas line 54B and a purge gas supplied from the purge line 55B are introduced via the switching valve 52B and the processing gas nozzle 16B into the processing space A1. It is also possible to discharge the second processing gas supplied from the gas line 54B and the purge gas supplied from the purge line 55A via the switching valve 52B and the gas exhaust line 53B.

The first processing gas introduced via the processing gas nozzle 16A flows along the surface of the substrate W1 in the processing space A1 formed in the reaction container 12 and is discharged via the exhaust opening 15B and the high-speed rotary valve 17B at the opposite end. Similarly, the second processing gas introduced via the processing gas nozzle 16B flows along the surface of the substrate W1 in the processing space A1 formed in the reaction container 12 and is discharged via the exhaust opening 15A and the high-speed rotary valve 17A at the opposite end.

Thus, the substrate processing apparatus 10 is configured to deposit a film atomic layer by atomic layer by alternately sending the first processing gas from the processing gas nozzle 16A to the exhaust opening 15B and sending the second processing gas from the processing gas nozzle 16B to the exhaust opening 15A. In this deposition process, a step to discharge the first processing gas from the processing space A1 is preferably provided between a step of supplying the first processing gas into the processing space A1 and a subsequent step of supplying the second processing gas. For example, the first processing gas may be discharged by supplying a purge gas into the processing space A1 or by evacuating the processing space A1. Similarly, a step to discharge the second processing gas from the processing space A1 is preferably provided between a step of supplying the second processing gas into the processing space A1 and a subsequent step of supplying the first processing gas. For example, the first processing gas may be discharged by supplying a purge gas into the processing space A1 or by evacuating the processing space A1.

When forming a high-dielectric-constant film comprising a metal oxide or a metal oxide compound on a substrate, a gas containing a metallic element such as Hf or Zr may be used as the first processing gas and an oxidizing gas such as O₃, H₂O, or H₂O₂ that oxidizes the metallic-element containing gas may be used as the second processing gas.

As described above, one problem with a conventional substrate processing apparatus is that a film forming process is influenced by a processing gas flowing from the processing space A1 into the external space A2 or from the external space A2 back into the processing space A1.

To obviate this problem and thereby to stably form a film that is uniform in thickness and quality, the substrate processing apparatus 10 of this embodiment has a mechanism as described below that controls the flow of a processing gas by adjusting the difference in pressure between the processing space A1 and the external space A2.

The substrate processing apparatus 10 of this embodiment may include a pressure-adjusting gas introducing line that communicates with the external space A2 and introduces a pressure-adjusting gas into the external space A2, and an exhaust line that communicates with the external space A2 and is connected to an exhaust unit for discharging the pressure-adjusting gas.

In this embodiment, a pressure-adjusting gas introducing line 11h for introducing a pressure-adjusting gas into the external space A2 is formed in the cover plate 11A and the pressure-adjusting gas introducing line 11h is connected to a pressure-adjusting gas line 56.

Also, an exhaust line 57 for evacuating the external space A2 is connected, for example, to the bottom of the external container 11B and the exhaust line 57 is connected to an exhaust unit such as a vacuum pump (not shown).

With this mechanism for supplying a pressure-adjusting gas into the external space A2, the substrate processing apparatus 10 of this embodiment makes it possible to reduce the difference in pressure between the external space A2 and the processing space A1 and thereby to reduce the amount of a processing gas flowing from the processing space A1 into the external space A2.

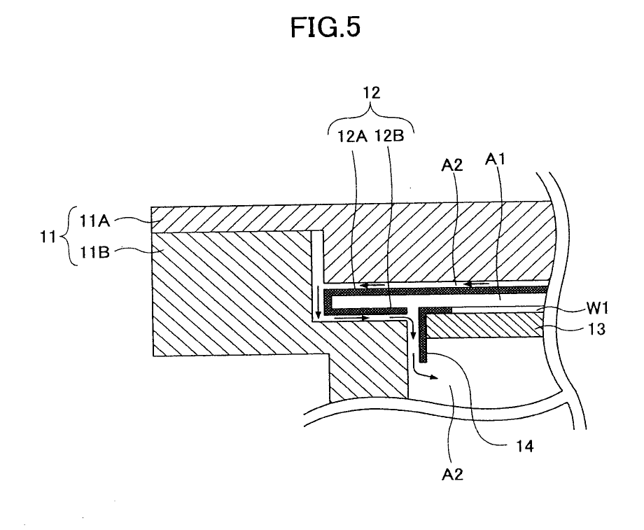

FIG. 5 is an enlarged cross-sectional view of a portion of the substrate processing apparatus 10 taken along line Y-Y shown in FIG. 3. In FIG. 5, the same reference numbers are used for parts corresponding to those shown in the previous figures, and descriptions of those parts are omitted.

As shown in FIG. 5, the processing space A1 and the external space A2 are connected, for example, via a gap around the holding table 13. More specifically, the processing space A1 and the external space A2 are connected via a gap formed between the guard ring 14 surrounding the substrate W1 held on the holding table 13 and an opening of the lower container 12B.

With the substrate processing apparatus 10 of this embodiment, the difference in pressure between the processing space A1 and the external space A2 is reduced and therefore the amount of a processing gas flowing from the processing space A1 via the gap into the external space A2 is reduced.

The pressure in the external space A20 is preferably the same as that in the processing space A10. However, it is not always necessary that the pressure in the external space A20 be exactly the same as that in the processing space A10.

The difference in pressure between the processing space A10 and the external space A20 is preferably in such a range that it does not substantially affect formation of a film (that it does not degrade the within-wafer uniformity of a formed film). In the descriptions below, that the pressure in the external space A10 is substantially the same as that in the processing space A20 means that the difference is within such a range.

Meanwhile, the pressure-adjusting gas supplied into the external space A2 is discharged through the exhaust line 57. The pressure-adjusting gas supplied into the external space A2 flows through a space between the cover plate 11A and the upper container 12A, through a space between the lower container 12B and the external container 11B, and through a space between the guard ring 14 and the external container 11B, and is then discharged from the exhaust line 57. Also, even if a processing gas flows from the processing space A1 into the external space A2, the processing gas is carried by the flow of the pressure-adjusting gas and discharged from the exhaust line 57. This configuration makes it possible to prevent degradation of the uniformity in thickness and quality of a film formed on a substrate and thereby to stably form a high-quality film.

Also with this configuration, since a processing gas flowing into the external space A2 from the processing space A1 is immediately diluted by the pressure-adjusting gas, deposition of the processing gas in the external space A2 is prevented.

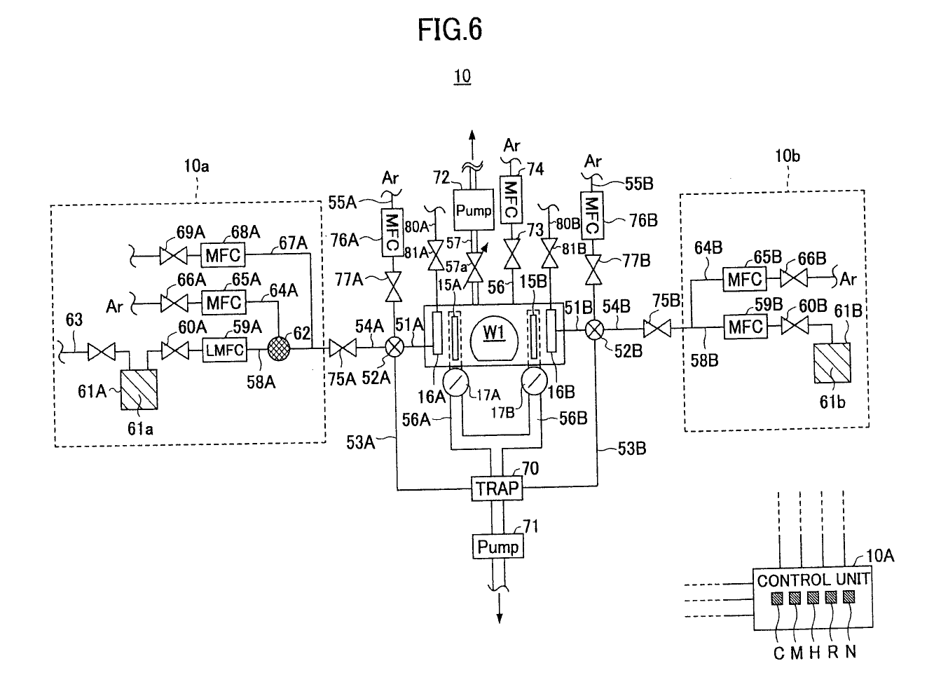

A schematic configuration of the substrate processing apparatus 10 is described below with reference to FIG. 6.

FIG. 6 is a drawing illustrating a schematic configuration of the substrate processing apparatus 10 shown in FIGS. 3 and 4. In FIG. 6, the same reference numbers are used for parts corresponding to those shown in the previous figures, and descriptions of those parts are omitted. Also, some parts of the substrate processing apparatus 10 shown in FIGS. 3 and 4 are omitted or simplified in FIG. 6.

As shown in FIG. 6, the processing gas nozzle 16A is connected to the switching valve 52A, the switching valve 52A is connected to the gas line 54A, and the gas line 54A is connected via a valve 75A to a processing gas supply unit 10a for supplying a first processing gas into the processing space A1. The switching valve 52A is also connected to the purge line 55A for supplying a purge gas into the processing space A1. The switching valve 52A switches connections so that the first processing gas is supplied into the processing space A1 or discharged from the exhaust line 53A connected to the switching valve 52A or so that the purge gas is supplied into the processing space A1 or discharged from the exhaust line 53A.

Similarly, the processing gas nozzle 16B is connected to the switching valve 52B, the switching valve 52B is connected to the gas line 54B, and the gas line 54B is connected via a valve 75B to a processing gas supply unit 10b for supplying a second processing gas into the processing space A1. The switching valve 52B is also connected to the purge line 55B for supplying a purge gas into the processing space A1. The switching valve 52B switches connections so that the second processing gas is supplied into the processing space A1 or discharged from the exhaust line 53B connected to the switching valve 52B or so that the purge gas is supplied into the processing space A1 or discharged from the exhaust line 53B.

The exhaust lines 53A and 53B are connected to a trap 70 and the trap 70 is connected to an exhaust unit 71 such as a vacuum pump for evacuating the trap 70.

The processing gas supply unit 10a includes a vaporizer 62 that is connected to the valve 75A and vaporizes a liquid material. The vaporizer 62 is also connected to a material line 58A for supplying a liquid material and a gas line 64A for supplying a carrier gas into the vaporizer 62.

The material line 58A is connected to a material container 61A for holding a material 61a that is in liquid form at ambient temperature. When a valve 60A is opened, the material 61a is supplied into the vaporizer 62 where it is vaporized. The flow rate of the material 61a flowing into the vaporizer 62 is controlled by a liquid mass flow controller 59A. The material 61a may be fed into the liquid mass flow controller 59A by pressing the material 61a with an inert gas such as He supplied from a gas line 63 connected to the material container 61A.

The gas line 64A is connected to a mass flow controller 65A and a valve 66A. When the valve 66A is opened, a carrier gas is supplied at a controlled flow rate into the vaporizer 62.

The first processing gas comprising the carrier gas and the material 61a vaporized by the vaporizer 62 is supplied into the gas line 54A when the valve 75 is opened and is then supplied into the processing space A1 or discharged through the exhaust line 53A via the switching valve 52A.

Also, if necessary, a gas line 67A leading to a mass flow controller 68A and a valve 69A may be connected between the valve 75A and the vaporizer 62. For example, the gas line 67A may be used to supply an assist gas to dilute the first processing gas or add another ingredient to the first processing gas. Alternatively, the assist gas may be used as a processing space pressure adjusting gas for adjusting the pressure in the processing space A1. Adjusting the flow rate of the processing space pressure adjusting gas makes it possible to reduce or substantially eliminate the difference in pressure between the processing space A1 and the external space A2.

The purge line 55A extending from the switching valve 52A is connected to a mass flow controller 76A and a valve 77A. When the valve 77A is opened, a purge gas for purging the processing space A1 is supplied at a controlled flow rate into the processing space A1.

The processing gas supply unit 10b includes a material line 58B and a gas line 64B connected to the valve 75B. The material line 58B is connected to a mass flow controller 59B, a valve 60B, and a material container 61B for holding a material 61b comprising an oxidizing gas for oxidizing the material 61a. The gas line 64B is connected to a mass flow controller 65B and a valve 66B. When the valves 66B, 60B, and 75B are opened, a second processing gas comprising the material 61b and a carrier gas is supplied via the switching valve 52B into the processing space A1. It is also possible to discharge the second processing gas from the exhaust line 53B by switching the switching valve 52B.

The purge line 55B extending from the switching valve 52B is connected to a mass flow controller 76B and a valve 77B. When the valve 77B is opened, a purge gas for purging the processing space A1 is supplied at a controlled flow rate into the processing space A1.

The first processing gas, the second processing gas, or the purge gas supplied into the processing space A1 as described above is discharged through the exhaust openings 15A and 15B, the high-speed rotary valves 17A and 17B, and the exhaust pipes 56A and 56B. The exhaust pipes 56A and 56B are connected to the trap 70 and the trap 70 is connected to the exhaust unit 71. The exhaust unit 71 evacuates the trap 70.

The processing gas nozzles 16A and 16B are connected, respectively, to vent lines 80A and 80B having, respectively, valves 81A and 81B. The processing gas nozzles 16A and 16B can be purged by supplying a purge gas into them and opening the valves 81A and 81B.

For example, to smoothly purge the processing space A1 by supplying a purge gas into it through the processing gas nozzles 16A and 16B, it is preferable to purge a processing gas remaining in the processing gas nozzles 16A and 16B in advance using the purge gas.

The purge gas line 56 for supplying a purge gas into the external space A2 is connected to a valve 73 and a mass flow controller 74. When the valve 73 is opened, a purge gas is supplied at a controlled flow rate into the external space A2.

The exhaust line 57 for evacuating the external space A2 is connected to an exhaust unit 72 such as a vacuum pump.

Preferably, the exhaust line 57 has a variable conductance valve 57a. The variable conductance valve 57a makes it easier to control the pressure in the external space A2. In other words, the difference in pressure between the processing space A1 and the external space A2 can be reduced or substantially eliminated by adjusting the conductance of the variable conductance valve 57a.

Alternatively, a variable conductance mechanism may be provided for each of the high-speed rotary valves 17A and 17B so that the pressure in the processing space A1 can be adjusted using the high-speed rotary valves 17A and 17B. This configuration makes it possible to easily control the pressure in the processing space A1 and thereby to reduce or substantially eliminate the difference in pressure between the processing space A1 and the external space A2.

In FIG. 6, a material that is in liquid form at ambient temperature is used as an example of the material for the first processing gas. Alternatively, a material that is in solid form or gaseous at ambient temperature may be used for the first processing gas.

The substrate processing apparatus 10 of this embodiment also comprises a control unit 10A including a computer for controlling substrate processing such as a film forming process. The control unit 10A includes a storage medium that stores a program for controlling the substrate processing apparatus 10. The computer controls the substrate processing apparatus 10 according to the stored program to perform a substrate processing method.

For example, the control unit 10A includes a computer (CPU) C, a memory M, a storage medium H such as a hard disk, a removable storage medium R, a network connection unit N, and a bus (not shown) for connecting these components. The bus is also connected, for example, to valves, exhaust units, and mass flow controllers of the substrate processing apparatus 10. A program for controlling a deposition apparatus is stored in the storage medium H. Alternatively, the program may be obtained, for example, from the removable storage medium R or via the network connection unit N. The exemplary substrate processing method described below is performed by the substrate processing apparatus 10 according to a program stored in the control unit 10A.

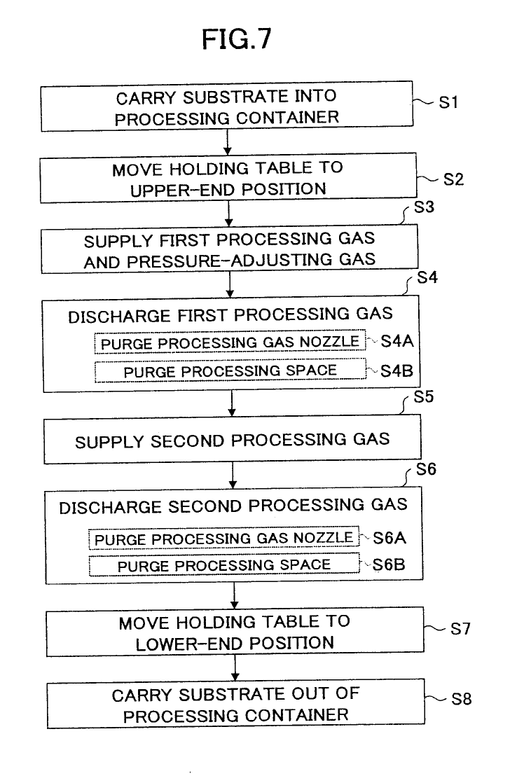

An exemplary process of forming a film using the substrate processing apparatus 10 is described below with reference to FIG. 7. FIG. 7 is a flowchart showing a substrate processing method according to the first embodiment.

In step 1 (indicated as S1 in FIG. 7; subsequent steps are also indicated in the same manner) shown in FIG. 7, a substrate is carried from a vacuum carrier chamber, which includes a carrier unit for carrying a substrate and is connected to the substrate processing apparatus 10, into the processing container 11 and placed on the holding table 13. The substrate is placed on the holding table 13 while the holding table 13 is at the lower-end position as shown in FIG. 4.

In step 2, the holding table 2 is moved to the upper-end position so as to form the processing space A1 together with the reaction container 12 as shown in FIG. 3.

In step 3, a first processing gas comprising the material 61a and a carrier gas is supplied as described below into the processing space A1 formed in step 2. In this exemplary process, it is assumed that a liquid organometallic compound (for example, tetrakis ethylmethylamino hafnium (TEAMH)) is used as the material 61a. The valves 75A, 60A, and 66A are opened to supply the material 61a and a carrier gas comprising, for example, Ar into the vaporizer 62. The flow rate of the material 61a is limited to, for example, 100 mg/min by the mass flow controller 59A and the flow rate of the carrier gas is limited to, for example, 400 sccm by the mass flow controller 65A.

In the vaporizer 62, the material 61a is vaporized and mixed with the carrier gas. The mixed gas is supplied together with an assist gas, which comprises, for example, Ar and is supplied at 600 sccm from the gas line 67A, into the processing space A1 via the switching valve 52A and the processing gas nozzle 16A.

The supplied first processing gas forms a laminar flow along the surface of the substrate and is discharged via the exhaust opening 15B and the high-speed rotary valve 17B. In this step, for example, about one molecular (or one atomic) layer of the material 61a contained in the first processing gas is adsorbed on the substrate.

In step 3 of this embodiment, a pressure-adjusting gas made of an inert gas such as Ar is supplied into the external space A2 surrounding the processing space A1 as shown in FIGS. 3 through 5. For example, the valve 73 is opened to supply the pressure-adjusting gas via the pressure-adjusting gas line 56 into the external space A2. The flow rate of the pressure-adjusting gas is limited to, for example, 1 slm by the mass flow controller 74. The pressure-adjusting gas reduces or substantially eliminates the difference in pressure between the processing space A1 and the external space A2 and thereby prevents the material molecules contained in the first processing gas from flowing out of the processing space A1 into the external space A2.

The pressure-adjusting gas is preferably supplied at least in step 3 or in a step where the first processing gas is supplied into the processing space A1. The pressure-adjusting gas may also be supplied in a different step.

The flow rate of the pressure-adjusting gas is preferably determined such that the pressure in the processing space A1 and the pressure in the external space A2 become substantially the same.

The difference in pressure between the processing space A1 and the external space A2 may also be controlled by adjusting the flow rate of the assist gas supplied into the processing space A1 in step 3. In this case, the flow rate of the assist gas is preferably determined such that the pressure in the processing space A1 and the pressure in the external space A2 become substantially the same.

Also, to smoothly purge the external space A2, the flow rates of the pressure-adjusting gas and the assist gas are preferably as high as possible within such ranges that the pressure in the processing space A1 and the pressure in the external space A2 become substantially the same.

In step 4, supply of the first processing gas into the processing space A1 is stopped and the first processing gas remaining in the processing space A1 is discharged.

In this step, for example, the first processing gas remaining in the processing nozzle 16A is purged first and then the processing space A1 is purged by supplying a purge gas from the processing gas nozzle 16A into the processing space A1. This method is preferable to smoothly discharge the first processing gas remaining in the processing space A1.

In other words, step 4 may include step 4A of purging a processing gas nozzle and step 4B of purging a processing space using the purged processing gas nozzle.

For example, in step 4A, an assist gas comprising, for example, Ar is supplied at 600 sccm from the gas line 67A into the processing gas nozzle 16A and, at the same time, the vent valve 81A is opened to purge the first processing gas remaining in the processing gas nozzle 16A.

Next, in step 4B, Ar from the purge line 55A and Ar from the gas line 67A are supplied both at 500 sccm via the processing gas nozzle 16A into the processing space A1 and are discharged from the opening 16B. As a result, the first processing gas remaining in the processing space A1 is purged.

After the supply of the purge gas is stopped, in step 5, a second processing gas comprising the material 61b and a carrier gas is supplied into the processing space A1. In this step, the valves 75B, 60B, and 66B are opened to supply the second processing gas comprising the material 61b and the carrier gas including, for example, Ar via the switching valve 52B and the processing gas nozzle 16B into the processing space A1. The flow rate of the material 61b is controlled by the mass flow controller 59B and the flow rate of the carrier gas is controlled by the mass flow controller 65B. When forming a metal oxide film such as HfO₂, an oxidizing gas comprising, for example, O₂ and O₃ is used as the material 61b. For example, O₃ having a density of 200 g/Nm³ is formed by introducing O₂ at 1000 sccm and N₂ at 0.1 sccm into an ozonizer and is supplied together with O₂ as the second processing gas into the processing space A1.

The supplied second processing gas forms a laminar flow along the surface of the substrate and is discharged via the exhaust opening 15A and the high-speed rotary valve 17A. When the second processing gas flows along the surface of the substrate, the material 61b reacts with the material 61a adsorbed on the substrate and forms one to three molecular layers of oxide.

In step 6, supply of the second processing gas into the processing space A1 is stopped and the second processing gas remaining in the processing space A1 is discharged.

In this step, for example, the second processing gas remaining in the processing nozzle 16B is purged first and then the processing space A1 is purged by supplying a purge gas from the processing gas nozzle 16B into the processing space A1. This method is preferable to smoothly discharge the second processing gas remaining in the processing space A1.

In other words, step 6 may include step 6A of purging a processing gas nozzle and step 6B of purging a processing space using the purged processing gas nozzle.

For example, in step 6A, an Ar gas is supplied at 600 sccm from the gas line 64B into the processing gas nozzle 16B and, at the same time, the vent valve 81B is opened to purge the second processing gas remaining in the processing gas nozzle 16B.

Next, in step 6B, Ar from the purge line 55B and Ar from the gas line 64B are supplied both at 500 sccm via the processing gas nozzle 16B into the processing space A1 and are discharged from the opening 16A. As a result, the second processing gas remaining in the processing space A1 is purged.

After step 6, the process returns to step 3 and steps 3 through 6 are repeated for a predetermined number of times to form a film with a desired thickness on the substrate. In this method, a film is formed by repeating formation of one to three molecular layers of materials using the surface reaction of the substrate. Therefore, this method makes it possible to form a film with higher quality compared with a conventional CVD method using vapor phase reaction.

After steps 3 through 6 are repeated for a predetermined number of times, the process proceeds to step 7.

In step 7, the holding table 13 is moved again to the lower-end position as shown in FIG. 4. Then, in step 8, the substrate is carried out of the processing container 11 into the vacuum carrier chamber, which includes the carrier unit for carrying a substrate and is connected to the substrate processing apparatus 10, and the process is terminated.

In the above substrate processing method, a reaction container is provided in a processing container of a substrate processing apparatus to form a dual space structure. This dual space structure makes it possible to minimize the space where a material gas flows and thereby to minimize the amount of a material gas that remains in or adheres to the processing container. With a conventional substrate processing apparatus, however, such a dual space structure causes a pressure difference between the internal space and the external space. Especially in the ALD method where supply and discharge of gases are repeated, the pressure difference causes flow of gas between the internal and external spaces and thereby makes a film non-uniform.

The exemplary substrate processing method of this embodiment makes it possible to reduce the difference in pressure between spaces in a dual space structure and thereby prevents the pressure difference from adversely affecting a film forming process.

In other words, the exemplary substrate processing method of this embodiment, while employing a dual space structure to reduce the volume of the processing space A1 and to improve the efficiency of supplying and discharging a processing gas, makes it possible to reduce adverse effects of a local pressure difference resulting from the dual space structure. This in turn makes it possible to form a high-quality film with excellent within-wafer uniformity.

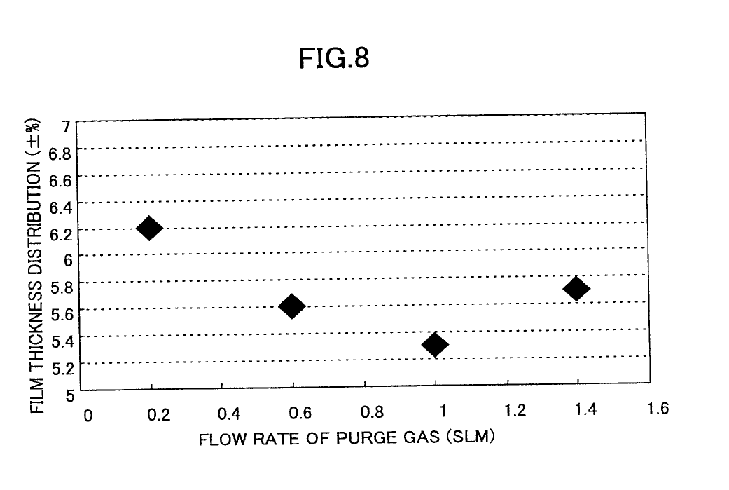

FIG. 8 is a graph showing changes in within-wafer uniformity in thickness of a film formed on a substrate using the above described method in relation to changes in flow rate of a pressure-adjusting gas supplied into the external space A2.

As shown in FIG. 8, when the flow rate of the pressure-adjusting gas is 0.2 slm, the within-wafer uniformity in film thickness distribution is 6.20. The within-wafer uniformity improves as the flow rate of the pressure-adjusting gas increases. In other words, the within-wafer uniformity improves as the difference in pressure between the processing space A1 and the external space A2 is decreased by increasing the pressure in the external space A2.

When the flow rate of the pressure-adjusting gas is 1 slm, the within-wafer uniformity in film thickness distribution is improved to 5.3%. If the flow rate of the pressure-adjusting gas becomes larger than 1 slm, the within-wafer uniformity is degraded. This indicates that if the flow rate of the pressure-adjusting gas becomes greater than a certain threshold, the pressure in the external space A2 becomes higher than that in the processing space A1 and the difference in pressure between the external space A2 and the processing space A1 starts to increase. As the results show, the flow rate of a pressure-adjusting gas or the pressure in the external space A2 is preferably determined such that the pressure in the processing space A1 and the pressure in the external space A2 become substantially the same.

### Second Embodiment

The present invention is not limited to the first embodiment described above. For example, variations and modifications may be made to the configuration of the substrate processing apparatus 10.

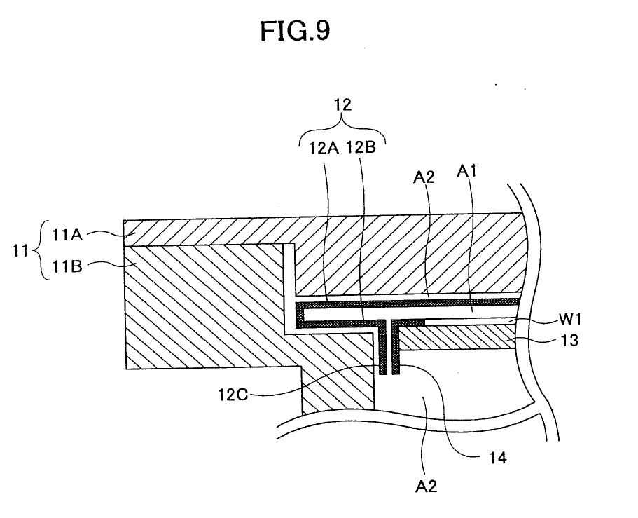

FIG. 9 is a drawing illustrating a variation of the substrate processing apparatus 10. In FIG. 9, the same reference numbers are used for parts corresponding to those shown in FIG. 5 of the first embodiment, and descriptions of those parts are omitted. Also, it is assumed that parts not described below have substantially the same functions as those of the first embodiment and substrate processing can be performed in substantially the same manner as described in the first embodiment.

In this embodiment, a conductance adjusting ring 12C having a substantially cylindrical shape is inserted between the guard ring 14 and the external container 11B.

The conductance adjusting ring 12C is connected to the edge of an opening of the lower container 12B. The opening of the lower container 12B has a substantially circular shape and accommodates the holding table 13 (or the guard ring 14). One end of the substantially cylindrical conductance adjusting ring 12C is connected to the edge of the opening.

With this structure, the conductance of a gap formed between the guard ring 14 and the external container 11B and connecting the processing space A1 and the external space A2 becomes smaller than that in the first embodiment. As a result, a material gas supplied into the processing space A1 is efficiently adsorbed on the substrate and the time necessary to reach saturation adsorption is reduced. This indicates that the amount of a material gas flowing from the processing space A1 into the external space A2 is reduced and use efficiency of the material gas is improved.

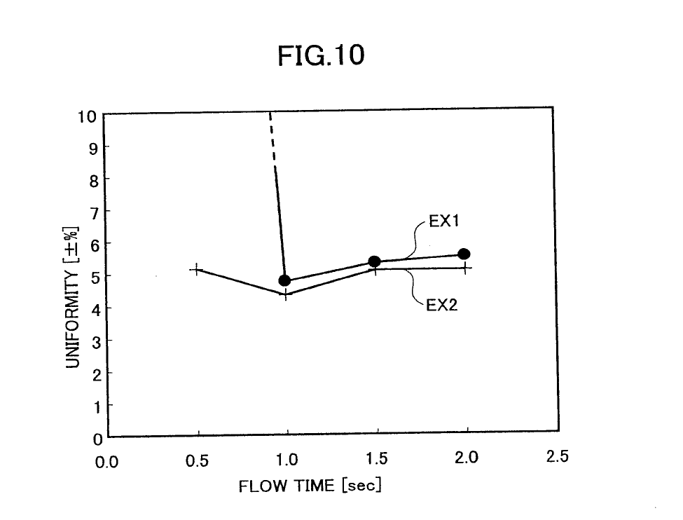

FIG. 10 is a graph showing within-wafer uniformity in film thickness distribution of films formed according the above described substrate processing method using substrate processing apparatuses of the first embodiment and the second embodiment. The horizontal axis of the graph indicates time used in step 3 shown in FIG. 7 (i.e. a length of time a material gas is supplied) and the vertical axis indicates the within-wafer uniformity. In the graph, EX1 indicates the results obtained using the substrate processing apparatus of the first embodiment and EX2 indicates the results obtained using the substrate processing apparatus of the second embodiment.

As shown in FIG. 10, in the case of EX1, if the material gas supplying time is reduced to less than one second, the within-wafer uniformity is dramatically degraded to such an extent that it is difficult to form a film.

On the other hand, in the case of EX2, the within-wafer uniformity is not degraded much even when the material gas supplying time is reduced to 0.5 seconds.

The results of EX2 indicate that use efficiency of the material gas is improved and saturation adsorption is reached in a short period of time because the amount of the material gas flowing out of the processing space A1 into the external space A2 is reduced. Also, the results of EX2 may indicate that the amount of the pressure-adjusting gas flowing from the external space A2 into the processing space A1 is reduced.

The present invention is not limited to the specifically disclosed embodiments, and variations and modifications may be made without departing from the scope of the present invention.

### INDUSTRIAL APPLICABILITY

The present invention relates to an apparatus or method for forming a film by alternately supplying multiple processing gases and makes it possible to control the flow of the processing gases in a space where a substrate is processed and thereby to improve the uniformity in thickness of a film to be formed on the substrate.

The present international application claims priority from Japanese Patent Application No. 2005-067777 filed on Mar. 10, 2005, the entire contents of which are hereby incorporated herein by reference.

1. An apparatus for processing a substrate, comprising:
a processing container including,
an external container having an opening,
a cover plate disposed to cover the opening of the external container, and
a reaction container disposed in the external container,
said reaction container defining a first space where the substrate is placed to be processed and defining a second space disposed above the first space and below the cover plate and separated from the first space;
a pair of processing gas supply units disposed so as to face each other across the substrate and configured to supply processing gases into the first space;
a pair of processing gas exhaust units disposed so as to face each other across the substrate and configured to discharge the processing gases; and
a pressure-adjusting gas supply unit configured to supply a pressure-adjusting gas for adjusting the pressure in the second space into the second space; and
a pressure-adjusting gas exhaust unit configured to evacuate the second space.

2. The apparatus as claimed in claim 1, further comprising:
a holding table disposed in the processing container and configured to hold the substrate, wherein a gap around the holding table separates a processing region of the reaction container from a non-processing region.

3. The apparatus as claimed in claim 2, wherein the holding table comprises a moveable table.

4. The apparatus as claimed in claim 2, wherein said first space adjoins said second space at said gap:

5. The apparatus as claimed in claim 2, further comprising:
a conductance adjusting ring disposed in the gap and configured to adjust a conductance of the gap.

6. The apparatus as claimed in claim 5, the conductance adjusting ring is located where the first space adjoins the second space at said gap.

7. The apparatus as claimed in claim 1, further comprising:
a variable conductance mechanism connected to at least one of the processing gas exhaust units.

8. The apparatus as claimed in claim 1, further comprising:
a control unit which controls substrate processing in the reaction container.

9. The apparatus as claimed in claim 8, wherein the control unit is programmed to:
control a supply of a first processing gas from the processing gas supply units into the first space;
control a discharge of the first processing gas from the first space;
control a supply of a second processing gas from the processing gas supply units into the first space; and
control a discharge of the second processing gas from the first space.

10. The apparatus as claimed in claim 9, wherein the control unit is configured to adjust a pressure in the second space by control of a pressure-adjusting gas supplied into the second space.

11. The apparatus as claimed in claim 2, further comprising:
a cylindrical conductance adjusting ring having an annular opening disposed in the gap, in gas flow communication with the first space by the annular opening, and forming a boundary between the first space and the second space.

12. The apparatus as claimed in claim 11, wherein said first space adjoins said second space below said cylindrical conductance adjusting ring and in the non-processing region:

13. The apparatus as claimed in claim 1, wherein at least one of the processing gas supply units includes at least one switching valve configured to switch a purge gas or at least one of the processing gases into the first space.

14. The apparatus as claimed in claim 13, wherein at least one of the processing gas supply units includes a purge gas supply.

15. The apparatus as claimed in claim 13, wherein at least one of the processing gas supply units includes a supply of a gas containing a metallic element.

16. The apparatus as claimed in claim 13, wherein at least one of the processing gas supply units includes a supply of a gas containing a metallic element of at least one Hf and Zr.

17. The apparatus as claimed in claim 13, wherein at least one of the processing gas supply units includes a supply of an oxidizing gas.

18. The apparatus as claimed in claim 13, wherein at least one of the processing gas supply units includes a supply of an oxidizing gas including at least one of O₃, H₂O, and H₂O₂.

19. The apparatus as claimed in claim 13, wherein at least one of the processing gas supply units includes a vaporizer that vaporizes a liquid material.

20. The apparatus as claimed in claim 19, further comprising a carrier gas supply to provide a carrier gas to the vaporized liquid material for transport to the reaction container.
